(19) United States
(12) Patent Application Publication
(10) Pub. No.: US 2026/0058074 A1
(43) Pub. Date: Feb. 26, 2026

(54) PUSH BUTTON DEVICE

(71) Applicant: SUNREX TECHNOLOGY CORP., Taichung City (TW)

(72) Inventors: Shih-Pin LIN, Taichung City (TW); Pei-Sin LIN, Taichung City (TW); Hsing-Kuang CHEN, Taichung City (TW)

(21) Appl. No.: 18/947,121

(22) Filed: Nov. 14, 2024

(30) Foreign Application Priority Data
Aug. 21, 2024 (TW) 113131453

(51) Int. Cl. H01H 13/14; H01H 13/02; H05K 1/02; H05K 1/18

(52) U.S. Cl. CPC H01H 13/14; H01H 13/023; H05K 1/0277; H05K 1/181; H05K 2201/10022

(57) ABSTRACT

A push button device includes a base plate, a film circuit board that includes a lower circuit board layer disposed on top of the base plate, a separating layer disposed on top of the lower circuit board layer, and an upper circuit board layer disposed on top of the separating layer, a flexible circuit board that includes a lower copper wire layer disposed on top of the upper circuit board layer, a base material layer disposed on top of the lower copper wire layer, and an upper copper wire layer disposed on top of the base material layer, a keycap that is disposed above the upper copper wire layer and that is light-transmissive, a supporting module, at least one resistor unit, and a light-emitting member that is disposed on the upper copper wire layer, and that is operable for emitting light directly to the keycap.

### CROSS-REFERENCE TO RELATED APPLICATION

This application claims priority to Taiwanese Invention Patent Application No. 113131453, filed on Aug. 21, 2024, the entire disclosure of which is incorporated by reference herein.

### FIELD

The disclosure relates to a push button device, and more particularly to a push button device for a backlight keyboard.

### BACKGROUND

A conventional backlight keyboard as disclosed in Taiwanese Invention Patent No. I681431 includes a light guide base plate, a supporting plate that has a light-transmissive portion, a plurality of keycaps, a plurality of elevating connectors, and a circuit board that has a hollow portion. The light guide base plate is made of a light-transmitting material, guides light to travel in a certain direction, and includes a plurality of assembly structures respectively connected to the elevating connectors. A light emitting member is disposed at a bottom of the light guide base plate, and emits light directed towards the light guide base plate. The light passes through the light guide base plate towards the supporting plate, and is reflected back to the light guide base plate by a reflective layer. Then, the light is converged, and travels in an upward direction through the light-transmissive portion of the supporting plate and the hollow portion of the circuit board to illuminate the keycaps. Hence, the conventional backlight keyboard can be used in low light environments.

However, when the light passes through the light guide base plate, some of the light rays are absorbed or scattered by the material of the light guide base plate. Furthermore, the reflective layer is not able to completely reflect the light rays, causing the light rays to be absorbed or scattered in different directions. Hence, the light emitted by the light emitting member is not effectively utilized, and the illuminating effect of the conventional backlight keyboard is lowered.

### SUMMARY

Therefore, an object of the disclosure is to provide a push button device that can alleviate at least one of the drawbacks of the prior art.

According to the disclosure, the push button device includes a base plate, a film circuit board, a flexible circuit board, a keycap, a supporting module, at least one resistor unit, and a light-emitting member. The film circuit board is pressable for generating a triggering signal, and includes a lower circuit board layer disposed on top of the base plate, a separating layer disposed on top of the lower circuit board layer, and an upper circuit board layer disposed on top of the separating layer. The flexible circuit board includes a lower copper wire layer disposed on top of the upper circuit board layer, a base material layer disposed on top of the lower copper wire layer, and an upper copper wire layer disposed on top of the base material layer. The keycap is disposed above the upper copper wire layer, and is light-transmissive. The supporting module includes a supporting member pivotally connected between the base plate and the keycap, and a resilient member disposed on the flexible circuit board and resiliently abutting against the keycap. The at least one resistor unit is disposed on the upper copper wire layer. The light-emitting member is disposed on the upper copper wire layer, and is operable for emitting light directly to the keycap.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an embodiment of a push button device according to the disclosure.

FIG. 2 is a partially exploded perspective view of the embodiment.

FIG. 3 is a partially exploded perspective view of a base plate, a film circuit board, and a flexible circuit board of the embodiment.

FIG. 4 is an exploded perspective view of the flexible circuit board, a plurality of resistor units, a light-emitting member and a transparent encapsulant of the embodiment.

FIG. 5 is a sectional view of the embodiment.

FIG. 6 is a fragmentary and partially enlarged view of FIG. 5.

FIG. 7 is another fragmentary and partially enlarged view of FIG. 5.

FIG. 8 is yet another fragmentary and partially enlarged view of FIG. 5.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

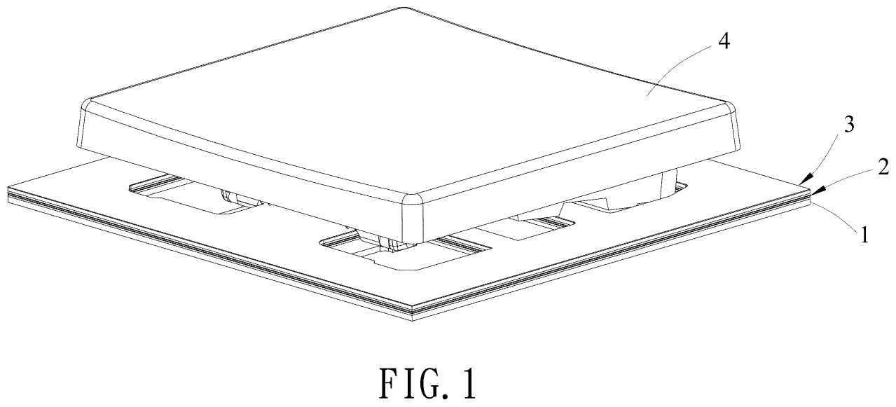

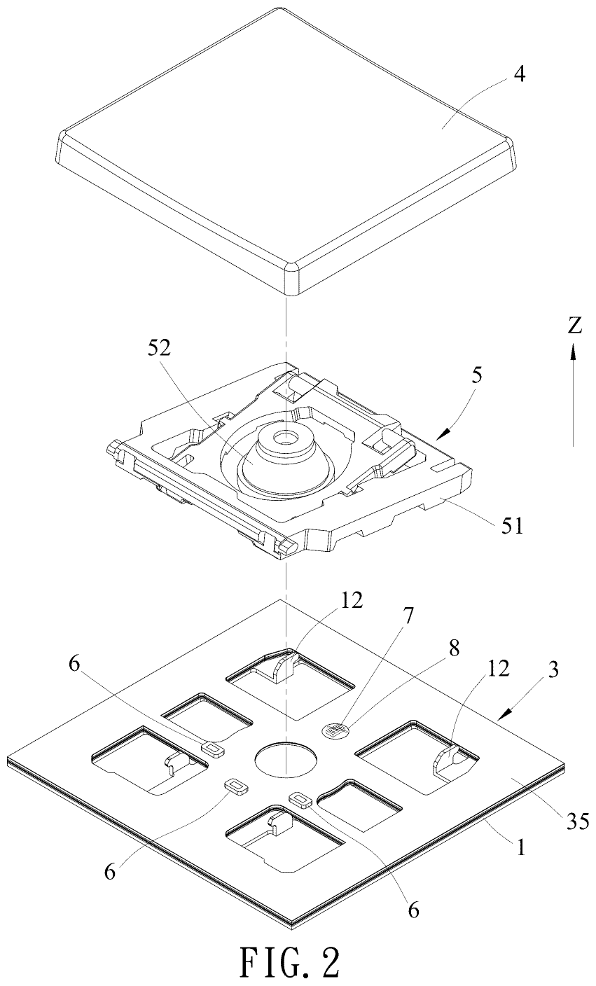

Referring to FIGS. 1 and 2, an embodiment of a push button device according to the disclosure includes a base plate 1, a film circuit board 2, a flexible circuit board 3, a keycap 4, a supporting module 5, at least one resistor unit 6, and a light-emitting member 7. In this embodiment, the at least one resistor unit 6 includes three resistor units 6.

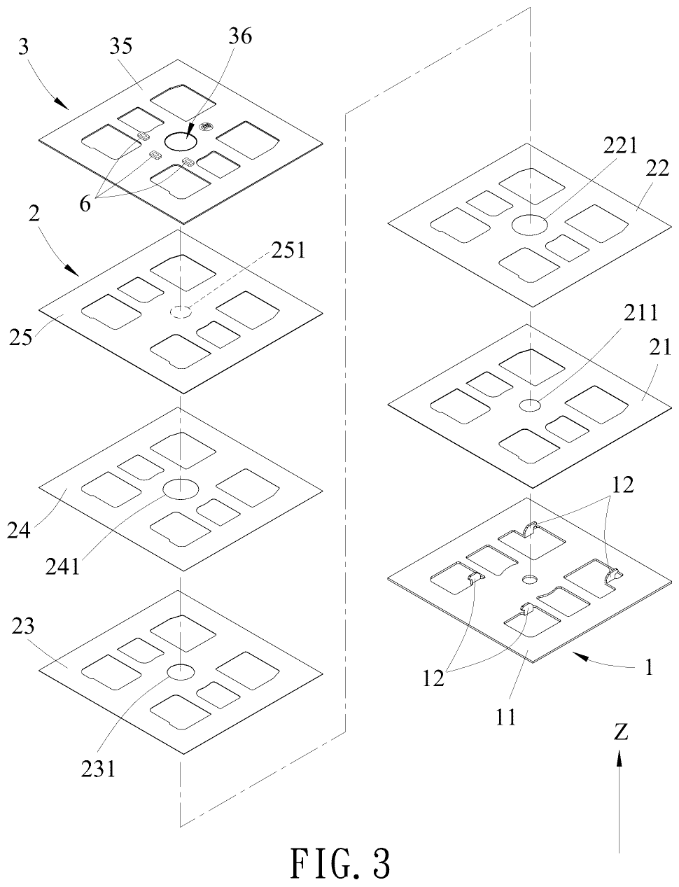

Referring to FIG. 3, the base plate 1 is made of metal, and has a top surface 11, and a plurality of connecting members 12 formed on the top surface 11.

Referring to FIG. 3, the base plate 1, the film circuit board 2, and the flexible circuit board 3 are stacked in order from bottom to top in an up-down direction (Z). That is, the film circuit board 2 is disposed on top of the base plate 1, and the flexible circuit board 3 is disposed on top of the film circuit board 2.

Referring to FIG. 3, the film circuit board 2 includes a lower circuit board layer 21 disposed on top of the base plate 1, a first transparent gel layer 22 disposed on top of the lower circuit board layer 21, a separating layer 23 disposed on top of the first transparent gel layer 22, a second transparent gel layer 24 disposed on top of the separating layer 23, and an upper circuit board layer 25 disposed on top of the second transparent gel layer 24.

Specifically, the separating layer 23 is disposed between the first and second transparent gel layers 22, 24, and is formed with a central hole 231.

The lower circuit board layer 21 is disposed on the top surface 11 of the base plate 1, and has a lower conducting portion 211 aligned with the central hole 231.

The first transparent gel layer 22 is disposed between the lower circuit board layer 21 and the separating layer 23, and has a first through hole 221 aligned with the central hole 231.

The second transparent gel layer 24 is disposed between the separating layer 23 and the upper circuit board layer 25, and has a second through hole 241 aligned with the lower conducting portion 211, the first through hole 221, and the central hole 231.

The upper circuit board layer 25 has an upper conducting portion 251 aligned with the lower conducting portion 211, the first through hole 221, the central hole 231, and the second through hole 241.

The film circuit board 2 is pressable for generating a triggering signal. Specifically, when the upper circuit board layer 25 is pressed, the lower circuit board layer 21 generates a triggering signal upon the upper conducting portion 251 contacting the lower conducting portion 211.

The lower circuit board layer 21, the separating layer 23, and the upper circuit board layer 25 cooperatively form an anti-ghosting circuit (not shown) with a ghost key suppression function; that is, in a keyboard having multiple push button devices of the disclosure, the push button devices that are pressed simultaneously may all be registered.

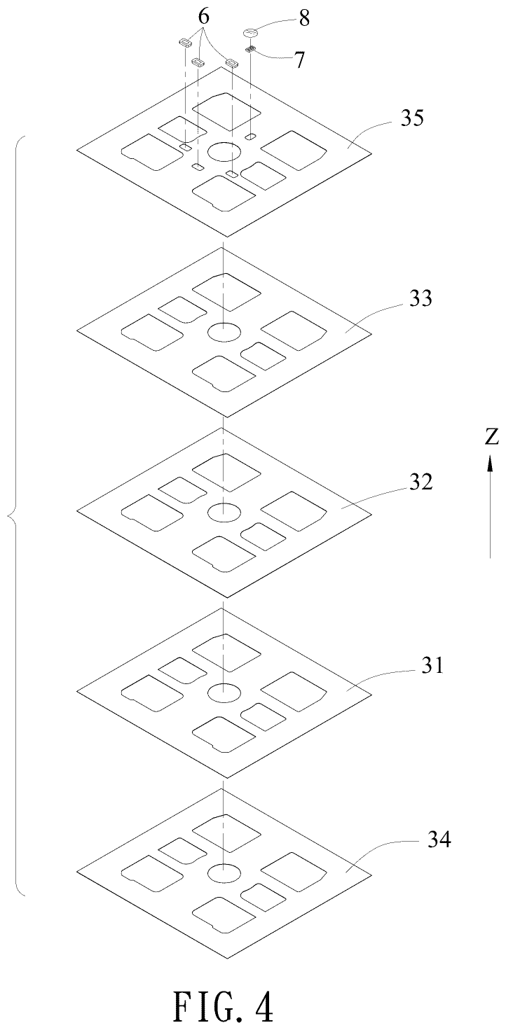

Referring to FIGS. 3 and 4, the flexible circuit board 3 includes a lower copper wire layer 31 disposed on top of the upper circuit board layer 25, a base material layer 32 disposed on top of the lower copper wire layer 31, an upper copper wire layer 33 disposed on top of the base material layer 32, a lower laminated cover layer 34 spread onto a bottom surface of the lower copper wire layer 31, and an upper laminated cover layer 35 spread onto a top surface of the upper copper wire layer 33.

The upper laminated cover layer 35 is formed by printing black ink onto the top surface of the upper copper wire layer 33.

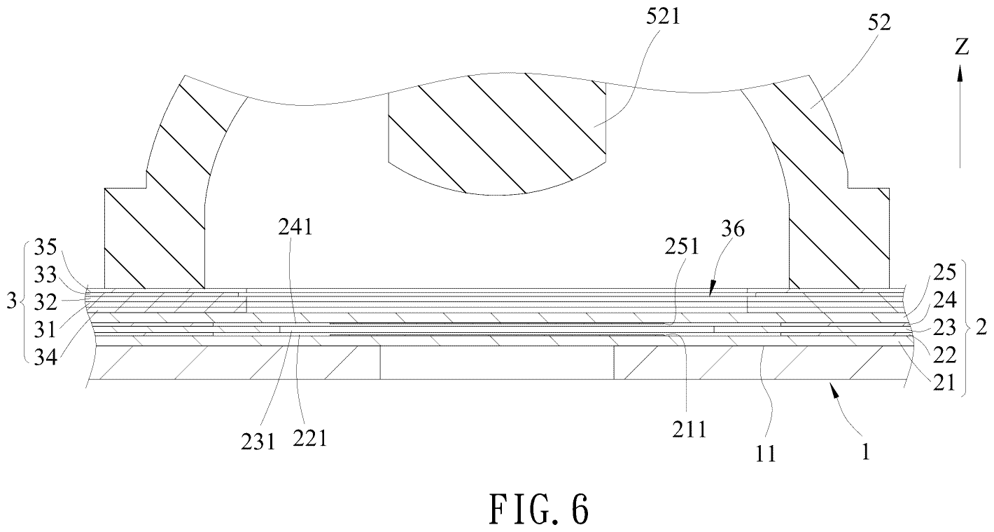

Referring to FIG. 6, in this embodiment, the lower copper wire layer 31, the base material layer 32, and the upper copper wire layer 33 cooperatively define a connecting passage 36 extending in the up-down direction (Z) and extending through the lower laminated cover layer 34 and the upper laminated cover layer 35, and aligned with the upper conducting portion 251, the central hole 231, and the lower conducting portion 211.

Referring to FIGS. 2 and 4, the keycap 4 is disposed above the upper copper wire layer 33, and has at least one light-transmissive portion (not shown). The light-transmissive portion may appear as text, symbols, or patterns.

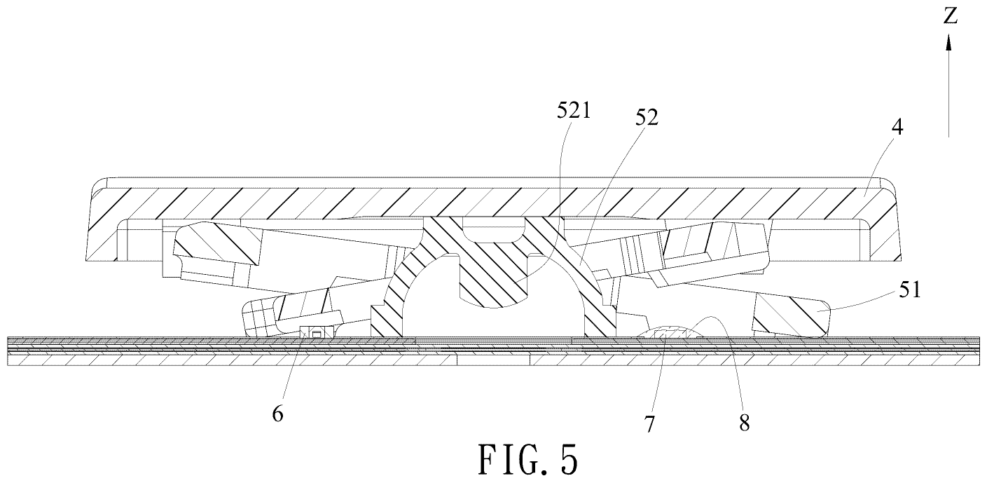

Referring to FIGS. 2, 5 and 6, the supporting module 5 includes a supporting member 51 pivotally connected between the keycap 4 and the connecting members 12 of the base plate 1, and a resilient member 52 disposed on the flexible circuit board 3 and resiliently abutting against the keycap 4. The resilient member 52 has a protrusion 521 aligned with the connecting passage 36. When the keycap 4 is pressed, the keycap 4 compresses the resilient member 52 and drives the protrusion 521 to move downwardly through the connecting passage 36 to push against the upper circuit board layer 25, which in turn drives the upper circuit board layer 25 to move downwardly, and when the upper conducting portion 251 of the upper circuit board layer 25 comes into contact with the lower conducting portion 211, the lower circuit board layer 21 generates a triggering signal.

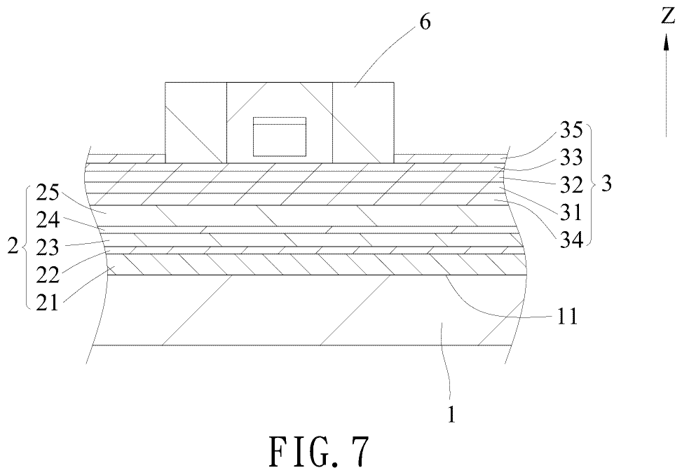

Referring to FIG. 7, the resistor units 6 (only one is shown) are disposed on the upper copper wire layer 33, and are used for controlling brightness of the light-emitting member 7 (see FIG. 2). Each of the resistor units 6 may be a carbon composition resistor, a carbon film resistor, a ceramic resistor, a metal element resistor, a metal fil resistor, a thin film resistor, a metal foil resistor, a metal oxide film resistor, a thick film resistor, or a wirewound resistor.

It should be noted that, a number of resistor units 6 may be changed as needed in other embodiments, and is not limited to three.

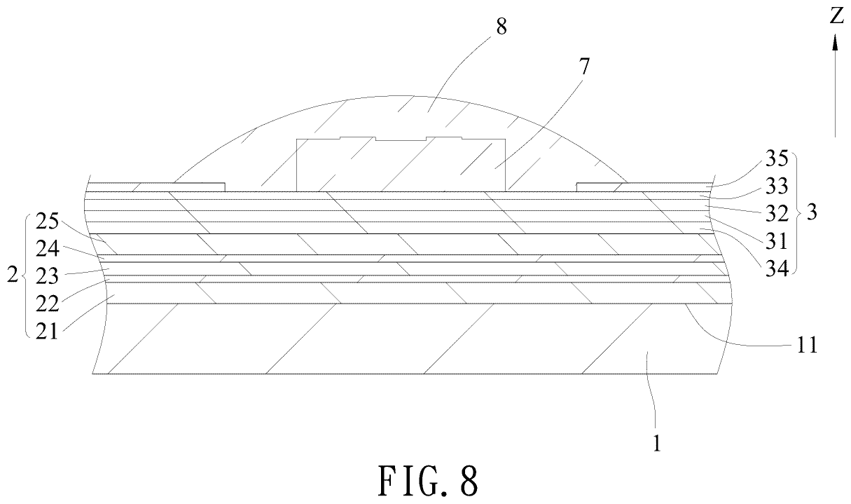

Referring to FIGS. 2, 5, and 8, in this embodiment, the light-emitting member 7 is a light-emitting diode (LED). The light-emitting member 7 is disposed on the upper copper wire layer 33, and is spaced apart from the resilient member 52. Specifically, since the light-emitting member 7 is disposed on the top surface of the upper copper wire layer 33, it is exposed and operable for emitting light directly to the keycap 4, so that light may be transmitted outwardly through the at least one light-transmissive portion of the keycap 4.

The upper copper wire layer 33, the base material layer 32, the lower copper wire layer 31, and the resistor units 6 cooperatively form an actuating circuit (not shown) for actuating the light-emitting member 7.

In other embodiments, by adjusting the number of the resistor units 6, different electrical resistances may be realized so that the brightness of the light-emitting member 7 may be adjusted. Adjusting the brightness of the light-emitting member 7 may also be achieved by using resistor units 6 with different resistance values. Furthermore, brightness of different light-emitting members with different specifications require different quantities of resistor units to control. For example, when the light-emitting member 7 is a mono color LED, only one resistor unit 6 is required to control the brightness of the light-emitting member 7. When the light-emitting member 7 is an RGB (red, green, and blue) LED, three resistor units 6 are required.

Referring to FIGS. 2, 4, and 8, the push button device further includes a transparent encapsulant 8 covering the light-emitting member 7 for protecting the light-emitting member 7, which prevents the light-emitting member 7 from being easily damaged from the exposure.

In conclusion, since the light-emitting member 7 is disposed on the upper copper wire layer 33 and is exposed, the light is emitted directly to the keycap 4 and transmitted outwardly through the at least one light-transmissive portion of the keycap 4, thereby increasing the illuminating effect of the push button device. Hence, the objective of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A push button device comprising:
a base plate;
a film circuit board that is pressable for generating a triggering signal, and that includes
a lower circuit board layer disposed on top of said base plate,
a separating layer disposed on top of said lower circuit board layer, and
an upper circuit board layer disposed on top of said separating layer;
a flexible circuit board that includes
a lower copper wire layer disposed on top of said upper circuit board layer,
a base material layer disposed on top of said lower copper wire layer, and
an upper copper wire layer disposed on top of said base material layer;
a keycap that is disposed above said upper copper wire layer, and that is light-transmissive;
a supporting module that includes
a supporting member pivotally connected between said base plate and said keycap, and
a resilient member disposed on said flexible circuit board and resiliently abutting against said keycap;
at least one resistor unit that is disposed on said upper copper wire layer; and
a light-emitting member that is disposed on said upper copper wire layer, and that is operable for emitting light directly to said keycap.

2. The push button device as claimed in claim 1, wherein said film circuit board further includes a first transparent gel layer disposed between said lower circuit board layer and said separating layer, and a second transparent gel layer disposed between said separating layer and said upper circuit board layer.

3. The push button device as claimed in claim 1, wherein said flexible circuit board further includes a lower laminated cover layer spread onto a bottom surface of said lower copper wire layer, and an upper laminated cover layer spread onto a top surface of said upper copper wire layer.

4. The push button device as claimed in claim 1, wherein:
said separating layer is formed with a central hole;
said lower circuit board layer has a lower conducting portion aligned with said central hole; and
said upper circuit board layer has an upper conducting portion aligned with said central hole.

5. The push button device as claimed in claim 4, wherein:
said lower copper wire layer, said base material layer, and said upper copper wire layer cooperatively define a connecting passage aligned with said upper conducting portion, said central hole, and said lower conducting portion; and
said resilient member has a protrusion aligned with said connecting passage.

6. The push button device as claimed in claim 1, further comprising a transparent encapsulant covering said light-emitting member.
